(19) United States
(12) Patent Application Publication
(10) Pub. No.: US 2009/0251223 A1
(43) Pub. Date: Oct. 8, 2009

(54) TECHNIQUES FOR CHARACTERIZING PERFORMANCE OF TRANSISTORS IN INTEGRATED CIRCUIT DEVICES

(76) Inventors: SANI R. NASSIF, Austin, TX (US); JAYAKUMARAN SIVAGNANAME, Austin, TX (US)

Correspondence Address: DILLON & YUDELL LLP, 8911 N. CAPITAL OF TEXAS HWY.,, SUITE 2110, AUSTIN, TX, 78759, US

(21) Appl. No.: 12/061,261

(22) Filed: Apr. 2, 2008

(51) Int. Cl. H03K 3/03; G01R 23/00; G06F 19/00

(52) U.S. Cl. 331/44; 331/57; 702/75

(57) ABSTRACT

A method, system and computer program product for characterizing FET transistors in an electronic circuit (IC) device using Performance Screen Ring Oscillator (PSRO) techniques. During PSRO testing, logic and non-logic bias voltages are applied to gate terminals of the being tested FETs to determine process-related variations and the relative strength of N-type and P-type transistors.

### BACKGROUND

1. Technical Field

The present invention generally relates to integrated circuit devices and in particular to techniques for characterizing performance of transistors in integrated circuit devices.

2. Description of the Related Art

As complexity of integrated circuit (IC) devices increases, computerized testing of the IC devices during manufacture and operation thereof has become increasingly more important. Many advanced IC devices such as, for example, Complementary-Metal-Oxide-Semiconductor (CMOS) IC devices, include large pluralities of N-type and P-type field effect transistors (N-FETs and P-FETs) and, in order for the IC device to operate properly, the relative performance of these transistors must be within specified ranges.

Performance Screen Ring Oscillator (PSRO) test monitors are commonly used as design/process improvement tools for characterizing operational properties of N-FETs and P-FETs fabricated in the same or different regions of a chip of the IC device. Several PSRO test monitors are described, for example, in U.S. Pat. No. 5,068,547 to Gascoyne and U.S. Pat. Nos. 5,486,786 and 5,686,855 to Lee. However, while present PSRO test monitors allow to detect variations in characteristics of N-FETs and P-FETs, computerized assessment of their relative performance remains a challenging task, and further improvements in the PSRO techniques are desirable.

### SUMMARY OF ILLUSTRATIVE EMBODIMENTS

Disclosed are a method, system, and computer program product for characterizing performance of transistors in integrated circuit (IC) devices.

In embodiments of the present invention, during a cycle of Performance Screen Ring Oscillator (PSRO) diagnostics in an IC device, logic and non-logic bias voltages are generated and applied to gate (channel) terminals of the being tested field effect transistors (FETs) to determine, using PSRO frequency measurements, process-related variations of parameters and the relative strength of the N-type and P-type transistors.

The above as well as additional features and advantages of the present invention will become apparent in the following detailed written description.

### BRIEF DESCRIPTION OF THE DRAWINGS

The invention itself will best be understood by reference to the following detailed description of an illustrative embodiment when read in conjunction with the accompanying drawings, wherein:

FIG. 1 is a block diagram of an exemplary integrated circuit (IC) device having a system of PSRO diagnostics including hardware and software components configured for implementing one or more embodiments of the invention;

FIG. 2 is a functional block diagram of a system of PSRO diagnostics in which the features of the invention are implemented, according to one embodiment of the invention; and

FIG. 3 illustrates a flow diagram of a process by which the features of the invention are implemented, according to one embodiment of the invention.

FIG. 4 is a chart illustrating results of exemplary computer simulation of parameters of transistors of the IC device of FIG. 1.

FIGS. 5A-5B are charts illustrating exemplary measurements performed using the system of FIG. 2.

FIG. 6 is a chart illustrating exemplary data obtained using the measurements performed in the system of FIG. 2.

### DETAILED DESCRIPTION OF AN ILLUSTRATIVE EMBODIMENT

The illustrative embodiments provide a method, system, and computer program product for characterizing performance of transistors in integrated circuit (IC) devices.

In the following detailed description of exemplary embodiments of the invention, specific exemplary embodiments in which the invention may be practiced are described in sufficient detail to enable those skilled in the art to practice the invention, and it is to be understood that other embodiments may be utilized and that logical, architectural, programmatic, mechanical, electrical, and other changes may be made without departing from the spirit or scope of the present invention. The following detailed description is, therefore, not to be taken in a limiting sense, and the scope of the present invention is defined only by the appended claims.

Within the descriptions of the figures, similar elements are provided similar names and reference numerals as those of the previous figure(s), except that suffixes may be added, when appropriate, to differentiate such elements. The specific numerals assigned to the elements are provided solely to aid in the description and not meant to imply any limitations (structural or functional) on the invention.

It is understood that the use of specific component, device and/or parameter names are for example only and not meant to imply any limitations on the invention. The invention may thus be implemented with different nomenclature/terminology utilized to describe the components/devices/parameters herein, without limitation. Each term utilized herein is to be given its broadest interpretation given the context in which that term is utilized. Specifically, as utilized herein, the term “PSRO” broadly refers to hardware/software products at least in part facilitating Performance Screen Ring Oscillator diagnostic techniques in an IC device.

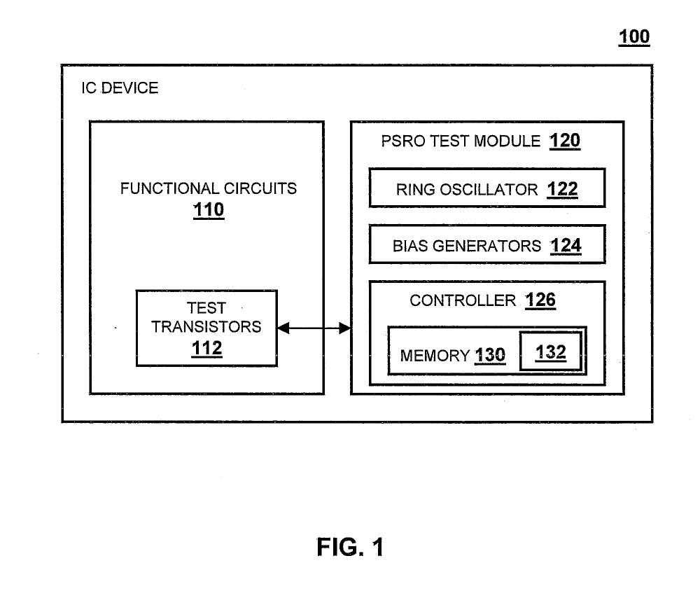

With reference now to the figures, FIG. 1 depicts a block diagram of exemplary IC device 100 comprising functional circuits 110 (e.g., CMOS functional circuits) including a plurality 112 of P-type and N-type test transistors (i.e., test FETs) and Performance Screen Ring Oscillator (PSRO) module 120. The PSRO module 120 generally includes ring oscillator 122, a plurality of bias generators 124, and controller 126 having memory 130 containing, among other software products, code of PSRO program 132. Controller 126 includes circuitry that administers the operation of other components of PSRO test module 120. Together, the PSRO module 120 and the test transistors 112 form a system of PSRO diagnostics of P-type and N-type transistors of IC device 100.

IC device 100 may, for example, be a microprocessor, an application-specific IC (ASIC), a field-programmable gate array (FPGA), or a memory array, among other types of IC devices. Correspondingly, memory module 130 may include, but is not limited to, cache memory, random access memory (RAM), read only memory (ROM), firmware memory devices, registers, and buffers, among other storage elements. Functional circuits 110 and PSRO module 120 are connected to external circuits by interfaces and/or busses (not shown) provided in IC device 100. In alternate embodiments, at least one of bias generators 124 or a portion thereof, memory 128, or PSRO program 132 may be associated with apparatuses external to IC device 100. In particular, PSRO program 132 may be executed by a remote processor (not shown), as well as controller 126 may be a portion of an apparatus (not shown) performing testing of IC device 100.

PSRO program 132 is illustrated and described herein as a stand-alone (i.e., separate) software/firmware component, which is saved in memory module 130 and provides or supports the specific novel functions discussed below. In alternate embodiments, at least portions of PSRO program 132 may be combined with other software modules incorporating functionality of their respective components.

In one illustrative embodiment, PSRO program 132 facilitates in-situ performance characterization of FETs in functional circuits 110 of IC device 100 based on measurements performed on test transistors 112. In particular, syntax of PSRO program 132 allows comparative testing of characteristics and relative strength of P-type and N-type test transistors 112.

Among the software code/instructions provided by PSRO program 132 and which are specific to the invention, are: (a) code for applying logic and non-logic bias voltages to gate (channel) terminals of P-type transistors and N-type transistors tested using a ring oscillator, and (b) code for measuring in the ring oscillator at least one of: (b1) a frequency f₀ at simultaneously applied (i) logic ‘0’—to gate terminals of the P-type transistors, and (ii) logic ‘1’—to gate terminals of the N-type transistors, (b2) a frequency f₁ at simultaneously applied (i) at least one non-logic value of P-bias voltage—to gate terminals of the P-type transistors, and (ii) logic ‘1’—to gate terminals of the N-type transistors, and (b3) a frequency f₂ at simultaneously applied (i) at least one non-logic value of N-bias voltage—to gate terminals of the N-type transistors, and (ii) logic ‘0’—to gate terminals of the P-type transistors.

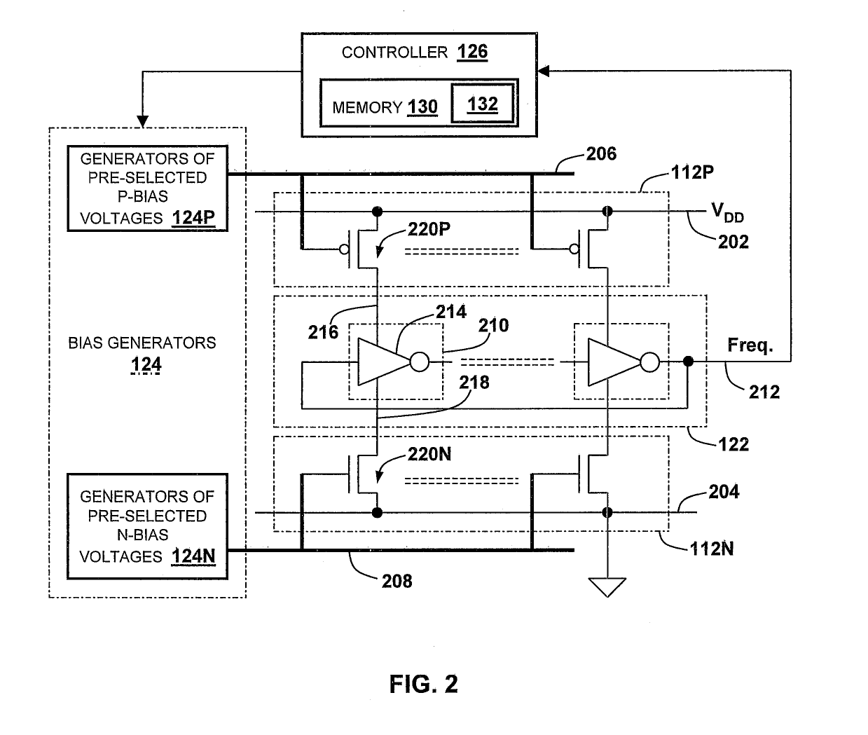

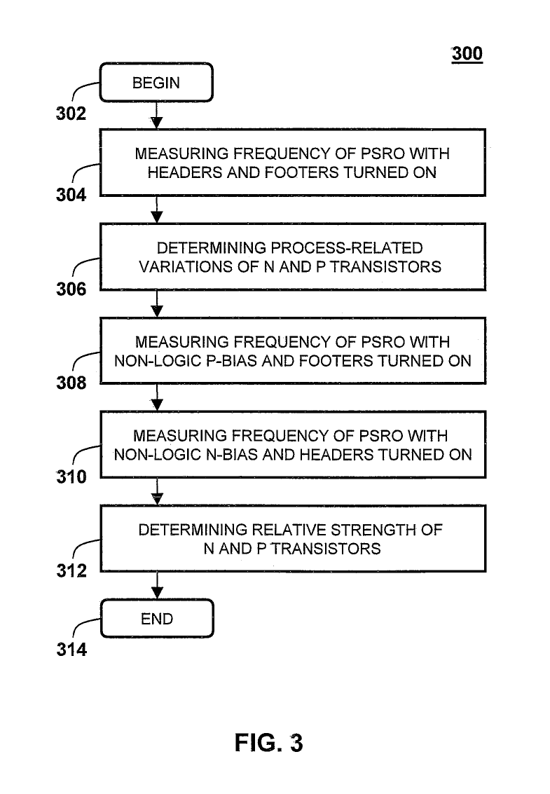

For simplicity of the description, the collective body of the code that enables these various features is referred to herein as PSRO program 132. According to the illustrative embodiment, when IC device 100 (or, alternatively, a remote processor) executes PSRO program 132, a series of functional processes is initiated that enables the above functional features, as well as additional features/functionalities that are described below within the context of FIGS. 2 and 3.

Those of ordinary skill in the art will appreciate that hardware and software configurations depicted in FIGS. 1 and 2 may vary. For example, other hardware or software components may be used in addition to or in place of the depicted components. The IC device 100 depicted in FIG. 1 may, for example, be a portion of a larger IC device or a system-on-chip (SoC), system-in-package (SiP), and system-in-module (SiM) device, as well as may incorporate some of such devices or elements thereof. Therefore, the architecture depicted in FIG. 1 is a basic illustration of an IC device, for which actual implementations may vary. Thus, the depicted example is not meant to imply architectural limitations with respect to the present invention.

With reference now to FIGS. 2 and 3, therein are described illustrative embodiments of the invention. FIG. 2 illustrates a high-level functional block diagram of PSRO test module 120, in which an embodiment of the invention is implemented, and FIG. 3 is a flow chart illustrating process 300 by which methods of the illustrative embodiments are completed. Although the features illustrated in FIGS. 2 and 3 may be described with reference to components shown in FIG. 1, it should be understood that this is merely for convenience and alternative components and/or configurations thereof can be employed when implementing embodiments of the invention.

Referring to FIG. 2, ring oscillator 122 of PSRO test module 120 includes a plurality of cascaded stages 210 that, together, form a close-loop oscillator circuit having a frequency output 212. Illustratively, in the depicted embodiment, stages 210 comprise inverters 214, and the frequency at output 212 is measured using controller 126.

Bias generators 124 include generators 124P of pre-selected P-bias voltages and generators 124N of pre-selected N-bias voltages, respectively, and are operable independently from one another. Pre-selected P-bias and N-bias voltages are disposed within operational ranges of gate (channel) voltages of the FETs in IC 100. In an alternate embodiment, the pre-selected bias voltages may be produced using tunable or switchable voltage sources.

Plurality 112 of test transistors comprises plurality 112P of P-type transistors 220P (i.e., P-type FETs) and plurality 112N of N-type transistors 220N (i.e., N-type FETs). Transistors 220P and 220N are selectively fabricated in pre-selected regions of a chip of IC device 100 and their characteristics are representative of the characteristics of other P-type and N-type transistors fabricated in these regions. Collectively, transistors 220P and 220N are referred to herein as “headers” and “footers” of ring oscillator 122, respectively.

Transistors 220P are selectively connected between an output power rail 202 of IC device 100 and high-potential power terminals 216 of inverters 214, and their gate terminals are connected to output rail 206 of generator(s) 124P of P-bias voltage. In operation, output power rail 202 is maintained at a power potential V_{DD} used in IC device 100. Correspondingly, transistors 220N are selectively connected between a low-potential power terminals 218 of stages 210 and common ground rail 204 of IC device 100, and their gate terminals are connected to output rail 208 of generator(s) 124N of N-bias.

Referring to FIG. 3, key portions of process 300 may be completed by PSRO program 132 executed in IC device 100 and controlling specific operations of/in PSRO test module 120, therefore the process 300 is described below in the context of either/both IC device 100 and PSRO test module 120. To best understand the invention, the reader should refer to FIGS. 2 and 3 simultaneously.

The process 300 of FIG. 3 begins at block 302, at which PSRO program 132 initiates PSRO test module 120. At block 304, bias generators 124P and 124N simultaneously provide bias voltages that turn ON (i.e., set to an ON state) transistors of the header (bias generator 124P) and the footer (bias generator 124P) of ring oscillator 122. In one embodiment, logic ‘0’ is applied to gate terminals of transistors 220P, and logic ‘1’ is applied to gate terminals of transistors 220N, respectively.

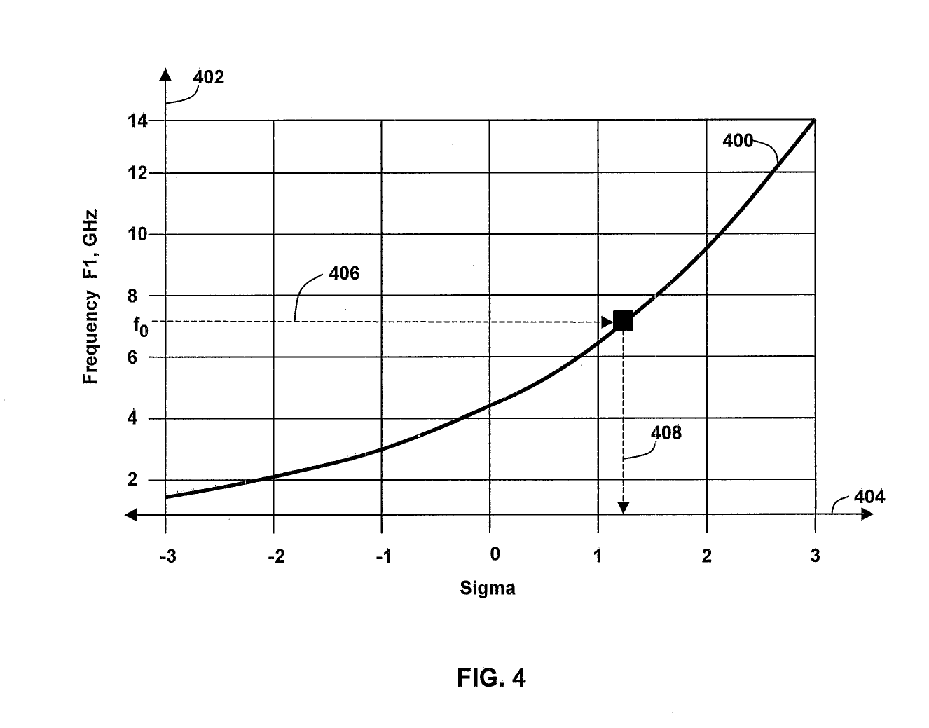

At block 306, frequency f₀ of ring oscillator 122 is measured and compared with a pre-determined frequency F1, which is calculated using computer models of transistors 220P, 220N and dependence of their characteristics from process variations during manufacture of the transistors. Referring to FIG. 4, an exemplary graph 400 illustrates dependence of frequency F1 (y-axis 402) from process variations expressed in units of standard deviation (i.e., “sigma”) (x-axis 404) for transistors 220P and 220N and transistors of bias generators 124 and ring oscillator 122, which are fabricated using 65 nm design rules and tested using a 7-stage ring oscillator 122. In FIG. 4, arrows 406, 408 illustrate how frequency f₀ may be used to assess process variations during manufacture of the N and P transistors.

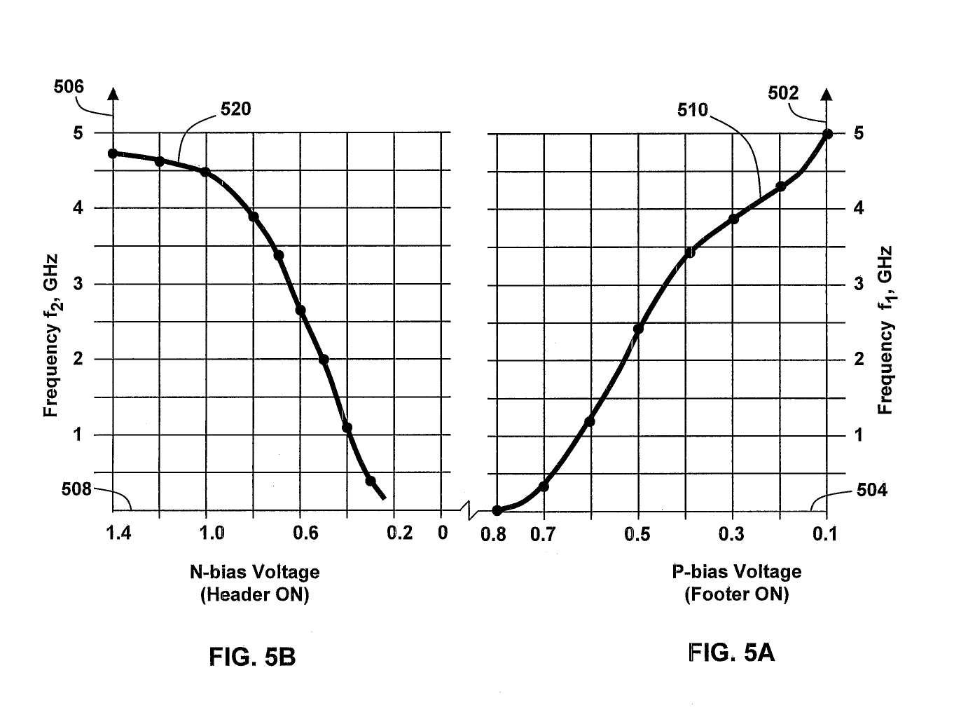

At block 308, frequency f₁ of ring oscillator 122 is measured at (i) a plurality of non-logic values of P-bias voltages disposed in an operational range of gate voltages of transistors in the header (transistors 220P) of ring oscillator 122 and (ii) an N-bias voltage turning ON transistors of the footer (transistors 220N) of ring oscillator 122. Each of the P-bias voltages is applied simultaneously with the N-bias voltage. In one embodiment, the bias voltage applied to gate terminals of transistors 220N corresponds to logic ‘1’. Exemplary results of these measurements are shown in FIG. 5A, where graph 510 depicts frequency f₁ (y-axis 502) as a function of a P-bias voltage (y-axis 504) produced by bias generator(s) 124P.

At block 310, frequency f₂ of ring oscillator 122 is measured at (i) a plurality of non-logic values of N-bias voltages disposed in an operational range of gate voltages of transistors in the footer (transistors 220N) of ring oscillator 122 and (ii) a P-bias voltage turning ON transistors of the header (transistors 220P) of ring oscillator 122. Each of the N-bias voltages is applied simultaneously with the P-bias voltage. In one embodiment, the bias voltage applied to gate terminals of transistors 220P corresponds to logic ‘0’. Exemplary results of these measurements are shown in FIG. 5B, where graph 520 depicts frequency f₂ (y-axis 506) as a function of a N-bias voltage (y-axis 508) produced by bias generator(s) 124N.

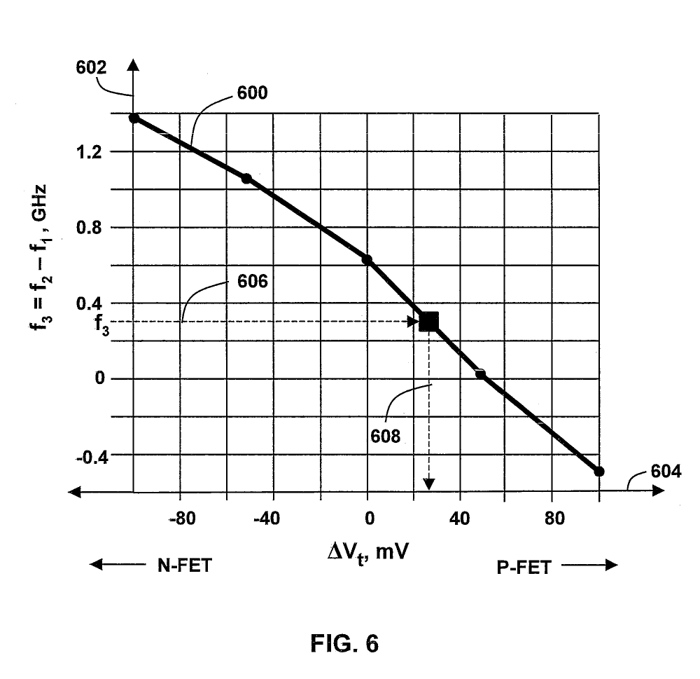

At block 312, for a particular set of P and N bias voltages, frequency f₃=f₂−f₁ is calculated and used to determine, based on computer models of transistors 220P and 220N, relative strength of transistors 220N versus transistors 220P. Referring to FIG. 6, an exemplary graph 600 illustrates the dependence of frequency f₃ (y-axis 602) due to the difference in the strength of the N and P devices, represented as ΔVₜ, a change in threshold voltage (x-axis 604) of transistors 220P and 220N fabricated using 65 nm design rules and tested using a 7-stage ring oscillator 122. In FIG. 6, arrows 606, 608 illustrate how voltage ΔVₜ may be determined based of a particular value of frequency f₃. Upon completion of procedures of block 312, process 300 ends.

In some embodiments, alternatively or additionally, the relative strength of transistors may be estimated at a plurality of pre-determined sets of the bias voltages, as well as IC device 100 may comprise several groups of P-type and N-type test transistors, which are selectively used as the headers and footers of a single ring oscillator 122.

In the flow chart in FIG. 3, one or more of the methods are embodied in a computer readable medium containing computer readable code such that a series of steps are performed when the computer readable code is executed on a computing device. In some implementations, certain steps of the methods are combined, performed simultaneously or in a different order, or perhaps omitted, without deviating from the spirit and scope of the invention. Thus, while the method steps are described and illustrated in a particular sequence, use of a specific sequence of steps is not meant to imply any limitations on the invention. Changes may be made with regards to the sequence of steps without departing from the spirit or scope of the present invention. Use of a particular sequence is therefore, not to be taken in a limiting sense, and the scope of the present invention is defined only by the appended claims.

As will be further appreciated, the processes in embodiments of the present invention may be implemented using any combination of software, firmware or hardware. As a preparatory step to practicing the invention in software, the programming code (whether software or firmware) will typically be saved in one or more machine readable storage mediums such as fixed (hard) drives, diskettes, optical disks, magnetic tape, semiconductor memories such as ROMs, PROMs, etc., thereby making an article of manufacture in accordance with the invention. The article of manufacture containing the programming code is used by either executing the code directly from the storage device, by copying the code from the storage device into another storage device such as a hard disk, RAM, etc., or by transmitting the code for remote execution using transmission type media such as digital and analog communication links. The methods of the invention may be practiced by combining one or more machine-readable storage devices containing the code according to the present invention with appropriate processing hardware to execute the code contained therein. An apparatus for practicing the invention could be one or more processing devices and storage systems containing or having network access to program(s) coded in accordance with the invention.

Thus, it is important that while an illustrative embodiment of the present invention is described in the context of a fully functional IC device with installed (or executed) software, those skilled in the art will appreciate that the software aspects of an illustrative embodiment of the present invention are capable of being distributed as a program product in a variety of forms, and that an illustrative embodiment of the present invention applies equally regardless of the particular type of media used to actually carry out the distribution. By way of example, a non-exclusive list of types of media includes recordable type (tangible) media such as floppy disks, thumb drives, hard disk drives, CD ROMs, DVDs, and transmission type media such as digital and analogue communication links.

While the invention has been described with reference to exemplary embodiments, it will be understood by those skilled in the art that various changes may be made and equivalents may be substituted for elements thereof without departing from the scope of the invention. In addition, many modifications may be made to adapt a particular system, device or component thereof to the teachings of the invention without departing from the essential scope thereof. Therefore, it is intended that the invention not be limited to the particular embodiments disclosed for carrying out this invention, but that the invention will include all embodiments falling within the scope of the appended claims. Moreover, the use of the terms first, second, etc. do not denote any order or importance, but rather the terms first, second, etc. are used to distinguish one element from another.

What is claimed is:

1. A ring oscillator system of an integrated circuit (IC) device, the system comprising:
a plurality of cascaded stages forming a ring oscillator providing a frequency output;
a first source of a plurality of pre-determined logic and non-logic P-bias voltages;
a second source of a plurality of pre-determined logic and non-logic N-bias voltages;
a plurality of P-type transistors selectively connected between a power rail of the IC device and high-potential power terminals of the stages, said transistors having gate terminals connected to the first source;
a plurality of N-type transistors selectively connected between low-potential power terminals of the stages and a common ground rail of the IC device, said transistors having gate terminals connected to the second source.

2. The system of claim 1, wherein said P-bias voltages are disposed in an operational range of gate voltage of the P-type transistors.

3. The system of claim 1, wherein said N-bias voltages are disposed in an operational range of gate voltage of the N-type transistors.

4. The system of claim 1, wherein the first source and the second source are operable independently from one another.

5. The system of claim 1, further comprising a controller configured to operate the first and second sources and measure a frequency at the frequency output.

6. A method of characterizing transistors in an electronic circuit (IC) device, the method comprising:
fabricating a ring oscillator having a plurality of cascaded stages and providing a frequency output;
selectively connecting a plurality of P-type transistors between a power rail of the IC device and high-potential power terminals of the stages, said transistors having gate terminals connected to a first source of a plurality of pre-determined logic and non-logic P-bias voltages;
selectively connecting a plurality of N-type transistors between low-potential power terminals of the stages and a common ground rail of the IC device, said transistors having gate terminals connected to a second source of a plurality of pre-determined logic and non-logic N-bias voltages; and
measuring at the frequency output a frequency of the ring oscillator at pre-selected P-bias and N-bias voltages.

7. The method of claim 6, further comprising measuring at least one of:
a frequency f₀ at simultaneously applied (i) logic ‘0’—to gate terminals of the P-type transistors, and (ii) logic ‘1’—to gate terminals of the N-type transistors;
a frequency f₁ at simultaneously applied (i) at least one non-logic value of the P-bias voltages—to gate terminals of the P-type transistors, and (ii) logic ‘1’—to the gate terminals of the N-type transistors; and
a frequency f₂ at simultaneously applied (i) at least one non-logic value of the N-bias voltages—to gate terminals of the N-type transistors, and (ii) logic ‘0’—to the gate terminals of the P-type transistors.

8. The method of claim 7, further comprising:
estimating a value of process variation during manufacturing of the P-type and N-type transistors based on results of comparing the frequency f₀ versus a pre-determined frequency.

9. The method of claim 7, further comprising:
estimating a relative strength of the N-type transistors versus the P-type transistors based on a value of a frequency f₃=f₂−f₁.

11. A computer readable medium having a computer program product for performing characterization of transistors in an electronic circuit (IC) device having a ring oscillator, said computer readable medium comprising:
computer program code for applying logic and non-logic bias voltages to gate terminals of P-type and N-type transistors being tested using the ring oscillator; and
computer program code for measuring in the ring oscillator at least one of:
a frequency f₀ at simultaneously applied (i) logic ‘0’—to gate terminals of the P-type transistors, and (ii) logic ‘1’—to gate terminals of the N-type transistors;
a frequency f₁ at simultaneously applied (i) at least one non-logic value of P-bias voltage—to gate terminals of the P-type transistors, and (ii) logic ‘1’—to gate terminals of the N-type transistors; and
a frequency f₂ at simultaneously applied (i) at least one non-logic value of N-bias voltage—to gate terminals of the N-type transistors, and (ii) logic ‘0’—to gate terminals of the P-type transistors.

12. The computer readable medium of claim 11, further comprising:
computer program code for estimating a value of process variation during manufacturing of the P-type and N-type transistors based on results of comparing the frequency f₀ versus a pre-determined frequency.

13. The computer readable medium of claim 11, further comprising:
computer program code for estimating a relative strength of the N-type transistors versus the P-type transistors based on a value of a frequency f₃=f₂−f₁.
